(19) United States
(12) Patent Application Publication
(10) Pub. No.: US 2025/0167192 A1
(43) Pub. Date: May 22, 2025

(54) INTEGRATED CIRCUIT DIE STACK WITH A BRIDGE DIE

(71) Applicant: Advanced Micro Devices, Inc., Santa Clara, CA (US)

(72) Inventors: Arsalan ALAM, Austin, TX (US); Chandra Sekhar MANDALAPU, Lehi, UT (US); Liwei WANG, Austin, TX (US); Omkar Deepak GUPTE, Austin, TX (US); Anadi SRIVASTAVA, Austin, TX (US); Sai VADLAMANI, Austin, TX (US); Sri Ranga Sai BOYAPATI, Austin, TX (US); Manish DUBEY, Austin, TX (US)

(21) Appl. No.: 18/518,184

(22) Filed: Nov. 22, 2023

(51) Int. Cl. H01L 25/18; H01L 23/00; H01L 23/498; H01L 23/538; H01L 25/00; H01L 25/065

(52) U.S. Cl. CPC H01L 25/18; H01L 23/5386; H01L 24/06; H01L 24/08; H01L 25/0652; H01L 25/50; H01L 23/49827; H01L 24/16; H01L 2224/0612; H01L 2224/08145; H01L 2224/08225; H01L 2224/16225

(57) ABSTRACT

Disclosed herein is an integrated circuit die stack and an integrated circuit die package assembly having the integrated circuit die stack. The integrated circuit die stack includes first plurality of integrated circuit dice disposed in a first tier of the die stack, and the first plurality of integrated circuit dice include a first integrated circuit die and a bridge die. The integrated circuit die stack further includes a second plurality of integrated circuit dice disposed in a second tier of the die stack, and the second plurality of integrated circuit dice are stacked vertically above the first plurality of the integrated circuit dice of the first tier and include a second integrated circuit die and a third integrated circuit die. The bridge die couples with both the second integrated circuit die and the third integrated circuit die.

### TECHNICAL FIELD

Embodiments of the present invention generally relate to an integrated circuit die stack with a bridge die, and in particular, to an integrated circuit die stack with a bridge die configured to provide lateral communication for integrated circuit dice at higher tiers.

### BACKGROUND

Electronic devices, such as tablets, computers, copiers, digital cameras, smart phones, control systems and automated teller machines, among others, often leverage chip package assemblies for increased functionality. To increase processing capabilities, chip packaging schemes often form a die stack by vertically mounting a plurality of integrated circuit dice to a package substrate. The integrated circuit die stack may include integrated circuit dice for memory, logic, communication, power management, or other functions.

In an integrated circuit die stack, integrated circuit dice at higher tiers often need to communicate with each other at a high speed. The current designs of die stacks have not provided effective solutions for such high speed lateral communications for integrated circuit dice at higher tiers.

Therefore, a need exists for an improved integrated circuit die stack.

### SUMMARY

Disclosed herein is an integrated circuit die stack and an integrated circuit die package assembly containing the integrated circuit die stack. Disclosed herein is an integrated circuit die stack and an integrated circuit die package assembly having the integrated circuit die stack. The integrated circuit die stack includes first plurality of integrated circuit dice disposed in a first tier of the die stack, and the first plurality of integrated circuit dice include a first integrated circuit die and a bridge die. The integrated circuit die stack further includes a second plurality of integrated circuit dice disposed in a second tier of the die stack, and the second plurality of integrated circuit dice are stacked vertically above the first plurality of the integrated circuit dice of the first tier and include a second integrated circuit die and a third integrated circuit die. The bridge die couples with both the second integrated circuit die and the third integrated circuit die.

Disclosed herein is a method for manufacturing an integrated circuit die stack. The method includes manufacturing a bridge die and a plurality of first dice, the bridge die and the plurality of first dice including spare materials at an inactive side. The method further includes mounting the bridge die and the plurality of the first dice on a first carrier via an active side of the bridge die and the plurality of the first dice, disposing a gap fill material in gaps among the bridge die and the plurality of first dice, removing the spare materials of the bridge die and the plurality of the first dice from the inactive side, mounting the bridge die, the plurality of the first dice, and the first carrier on a second carrier, removing the first carrier, mounting a plurality of second dice on top of the bridge die and the plurality of the first dice, connecting the bridge die with at least two of the plurality of the second dice, mounting a third carrier on the plurality of the second dice; and removing the second carrier.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an electronic device having an integrated circuit die stack with a bridge die according to an embodiment of the present application.

FIG. 2a is a schematic close-up view of the dice at different tiers of FIG. 1, according to an embodiment of the present application.

FIG. 2b illustrates a schematic configuration of an IC die stack having three tiers of IC dice, according to an embodiment of the present application.

FIG. 2c illustrates a schematic configuration of an IC die stack having IC stacks at higher tiers, according to an embodiment of the present application.

FIG. 3a is a schematic cross-sectional view of the bridge die having a passive device according to an embodiment of the present application.

FIG. 3b illustrates a schematic cross-sectional view of another bridge die having a passive device, according to an embodiment of the present application.

FIG. 3c illustrates a schematic cross-sectional view of another bridge die having an active device, according to an embodiment of the present application.

FIG. 4 is a schematic manufacturing process for making a 3D integrated circuit die stack having a bridge die according to an embodiment of the present application.

FIG. 5 is a method of manufacturing an IC die stack, according to an embodiment of the present application.

FIG. 6 is another method of manufacturing an IC ide stack, according to an embodiment of the present application.

To facilitate understanding, identical reference numerals have been used, where possible, to designate identical elements that are common to the figures. It is contemplated that elements of one embodiment may be beneficially incorporated in other embodiments.

### DETAILED DESCRIPTION

An integrated circuit die stack is disclosed that provides a bridge die at a lower tier. The bridge die is configured to provide high speed lateral communication between integrated circuit dice disposed in a higher tier. The bridge die includes a redistribution layer built up on a top surface of a substrate, such as silicon, glass, or any other suitable substrate. The redistribution layer couples with the integrated circuit dice disposed in the higher tier via a plurality of hybrid bonds. Pitches of the hybrid bonds are denser than connections made by wire bonds or micro solder balls, thus enabling high density, high speed data transmission. The bridge die may further include a plurality of through silicon vias for power delivery and a plurality of integrated passive devices for power and signal integrity. The bridge die does not include active devices, such as transistors and the like.

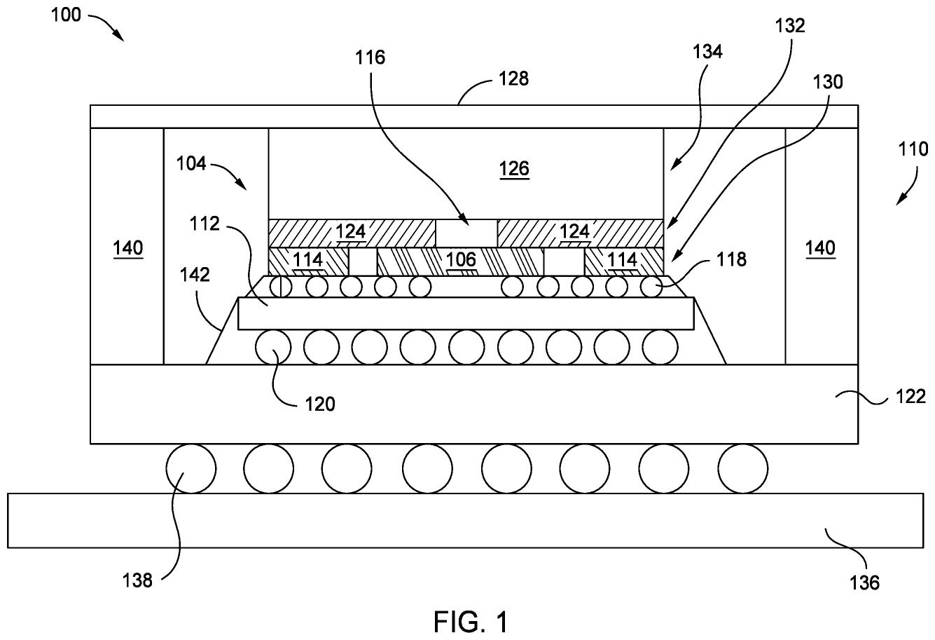

Turning now to FIG. 1, an exemplary integrated circuit (IC) die package assembly 110 is disposed on a printed circuit board (PCB) 136 and is connected with the PCB 136 via a plurality of electric connections 138, such as solder balls or other suitable connections. The IC die package assembly 110 and the PCB 136 together form at least part of an electronic device 100. The electronic device 100 may be a tablet, computer, copier, digital camera, smart phone, control system, automated teller machine, server or other solid-state memory and/or logic device. According to an embodiment, the IC die package assembly 110 includes a bridge die disposed at a bottom tier configured to provide high speed interconnection for dice disposed at higher tiers.

The IC die package assembly 110 includes an IC die stack 104 mounted to an optional interposer 112. According to an embodiment, the IC die stack 104 may be mounted directed to a package substrate 122. The IC die package assembly 110 further includes an optional stiffener 140 coupled with the package substrate 122 and configured to enhance the warpage resistance of the package substrate 122 against out of plane deformation. The IC die package assembly 110 further includes a lid 128 configured to cover the IC die stack 104 and dissipate heats generated by the IC die package assembly 110.

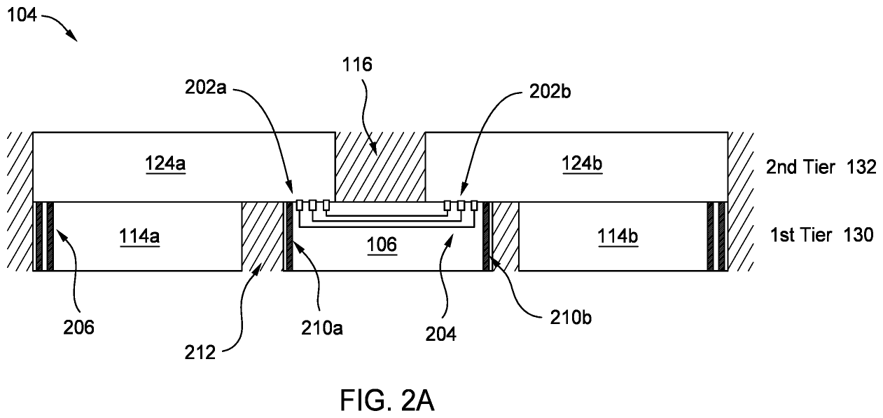

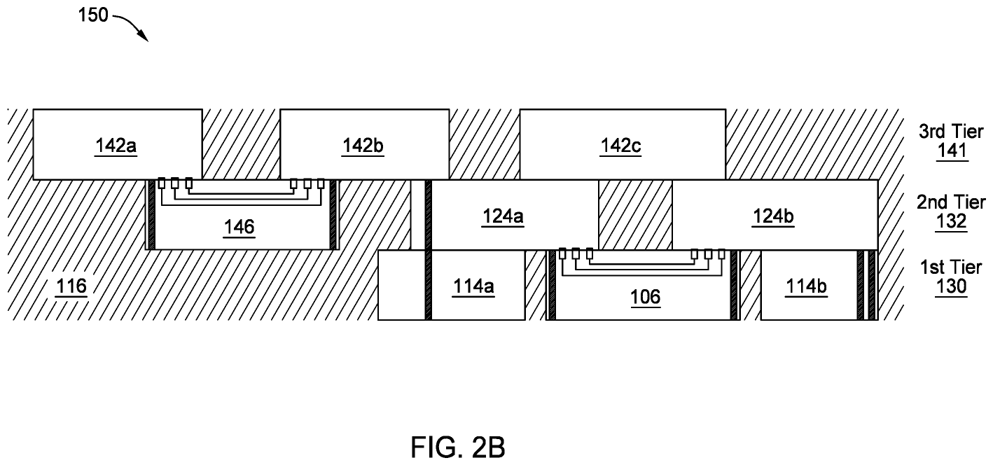

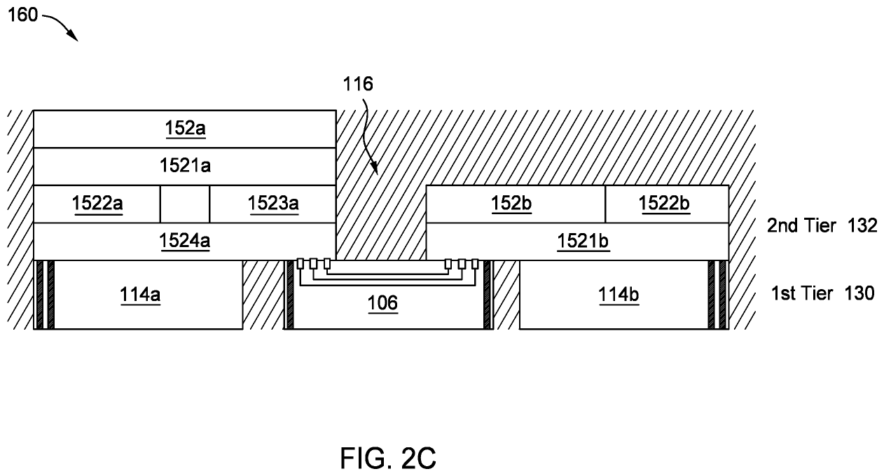

The IC die stack 104 includes a plurality of tiers of IC dice stacked vertically on top of each other. For example, three tiers of IC dice are shown in FIG. 1: a first tier 130, a second tier 132, and a third tier 134. IC dice disposed at the first tier 132 include two IC dice 114 and a bridge die 106, and are directly coupled with the interposer 112 or the package substrate 122. Two IC dice 124 are disposed at the second tier and stacked vertically above the IC dice 114. According to an embodiment, the two IC dice 124 in an upper tier communicate with each other via the bridge die 106 disposed in the adjacent lower tier. Each of the IC dice 124 may have a larger size than the IC dice 114. For example, the IC die 124 has a bottom surface area (length×width) that is greater than a top surface of the IC die 114. In the sectional view of FIG. 1 that illustrates lengths of the IC dice 114, 124 horizontally and heights vertically, the length of the bottom surface of the IC die 124 is greater than the length of the top surface of the IC die 114, such that the top surface of the IC die 114 is entirely covered by the bottom surface of the IC die 124. According to an embodiment, an upper surface of the bridge die 106 is co-planar with upper surfaces of the IC dice 114. A portion of each IC dice 124 overlays both the bridge die 106 and at least one of the IC dice 114. The bridge die 106 and the IC dice 114 are coupled to the IC dice 124 via a plurality of hybrid bonds 202 (FIG. 2). In the exampled depicted in FIG. 1, the third tier 134 includes a filler die 126 configured to fill the space between the second tier 132 and the lid 128. In one example, the filler die 126 is configured to raise the height of the IC die stack 104 to the same height as the stiffener 140. The filler die 126 may include a semiconductor substrates, such as a silicon substrate. In one example, the filler die 126 is not electrically connected to the dice 124 of the second tier. The IC die stack 104 is not limited to only three tiers. A greater or lesser number of tiers of IC dice may be included in the IC die stack 104. In addition, a greater or less number of IC dice may be included in each tier.

The IC dice 114 and 124 may be programmable logic devices, such as field programmable gate arrays (FPGA), memory devices, optical devices, processors or other IC logic structures. The interconnection among IC dice of different tiers may include wire bonds, hybrid bonds, or micro solder balls. The IC die stack 104 mounted to a top surface of the interposer 112 by die connections 118. The die connections 118 may be in the form of a plurality of solder joints, also known as “micro-bumps.”

The interposer 112 includes a circuitry for electrically connecting the IC die stack 104 to a circuitry of the package substrate 122. Solder connections 120, also known as or “package bumps” or “C4 bumps,” are utilized to provide an electrical connection between the circuitry of the interposer 112 and the circuitry of the package substrate 122. The package substrate 122 may be mounted and connected to the PCB 136, utilizing solder balls 138, wire bonding or other suitable technique.

An under molding 142 may be utilized to fill the space not taken by the solder connections 120 between the PCB 136 and the interposer 112 or the package substrate 122. A gap fill material 116 may be utilized to fill gaps within the IC die stack 104.

FIG. 2a illustrates a schematic configuration among IC dice at the first tier and second tier of the IC die stack 104, according to an embodiment. As described above, the bridge die 106 is disposed at the first tier 130 and is configured to couple with two dice 124a and 124b disposed at the second tier 132 that directly overlays the first tier 130. The IC dice 124a and 124b may have a larger size than the IC dice 114a and 114b. As a result, the IC die 124a covers the entire IC die 114a and also covers a part of the bridge die 106. Since the IC die 124a covers the entire IC die 114a, more space is available for routing between the dice 1124a, 114a, while still having space available for routings needed to establish high density interconnects between the IC die 124a and the bridge die 106. The same is true regarding the IC dice 124b and 114b. According to an embodiment, the bridge die 106 and the dice 124a and 124b are coupled via a plurality of hybrid bonds 202a and 202b. The hybrid bonds includes metal-to-metal bonds formed by a hybrid bonding process. For example, the metal-to-metal bonds may be formed using pressure and heat to form eutectic metal bonds. A hybrid bond may be formed by bonding the dielectric materials surrounding bond pads to first secure IC dice, followed by an interfusion of the metal materials of the bond pads to create the electric interconnect. The dielectric materials surrounding the bond pads is selected from a material suitable for hybrid bonding to another dielectric material. Materials that are suitable for hybrid bonding include polybenzoxazole (PBO), polyimide (PI), benzocyclobutene (BCB), a combination thereof, or the like.

The bridge die 106 further includes a plurality of routing connections 204 configured to couple the hybrid bonds 202a and 202b. The hybrid bonds 202a and 202b and the routing connections 204 are configured to provide lateral data connections between the dice 124a and 124b. According to an embodiment, the pitch among the hybrid bonds 202a or 202b is less than 10 μm, 5 μm, or 1 μm. The hybrid bonds of the bridge die 106 provides a significantly denser pitch of connections than wire bonds or micro solder balls. As a result, the communication bandwidth between the hybrid bonded IC dice 124a and 124b is significantly greater than conventional devices. According to an embodiment, the bridge die 106 includes through silicon vias (TSV) 210a and 210b that couple with the dice 124a and 124b. The TSV 210a couples the circuitry of the interposer 112 and/or the package substrate 122 to the die 124a overlaying the bridge die 106. The TSV 210b couples the circuitry of the interposer 112 and/or the package substrate 122 to the die 124b overlaying the bridge die 106. According to an embodiment, the bridge die 106 couples with an interposer 112 via a plurality of solder connections 118 (FIG. 1). The TSV 210 provides connectivity between the package substrate 122 and the dice of the first tier. The TSV 210 also provides connectivity between dice of different tiers. The TSV 210 may transfer several types of signals, including power, ground connection, data signal, testing signals, control signal, timing signal, encryption signal, or any other signals transmitted from a die to another die.

According to an embodiment, the dice 124a and 124b at the second tier couples with at least two dice 114 and 106 at the first tier. A gap 212 between the die 106 and the die 114 is filled with a gap fill material 116, such as a dielectric material. The gap fill material 116 also fills other gaps formed among the dice disposed at the first tier and the second tier. The die 124a at the second tier is not limited to couple with only 2 dice at the first tier. The die 124a may couple with 3, 4, or 5 dice at the first tier. According to an embodiment, at least one die at the first tier that couples with the die 124a is configured to be a bridge die that provides lateral data communication between the die 124a and another die disposed at the second tier.

According to an embodiment, the die 124a couples with the die 114 via any suitable connections, such as wire bonds, hybrid bonds, BEOL, or micro solder balls. The dice 114a and 114b may also include a plurality of TSVs 206 that couple with the dice 124a and 124b. In an example, a plurality of hybrid bonds couple the die 124a with the die 114a or couple the die 124b with the die 114b.

FIG. 2b illustrates a schematic configuration of an IC die stack 150 having three tiers of IC dice, according to an embodiment. The IC dies stack includes three (3) tiers of dice 130, 132, and 140, respectively. The 3^{rd} tier 141 includes a plurality of IC dice 142a, 142b, and 142c. A bridge die 146 is disposed at the 2^{nd} tier 132 that connects the dice 142a and 142b at the 3^{rd} tier. According to an embodiment, the present application may include additional tiers, such as a 4^{th} tier of IC dice. The bridge die 106 or 146 may be disposed in each tier of IC dice and configured to provide interconnection among dice at a higher tier. For example, the bridge tie may be disposed at the 3^{rd} tier to provide interconnection among dice at the 4^{th} tier.

FIG. 2c illustrates a schematic configuration of an IC die stack 160, according to an embodiment. The IC die stack 160 has two tiers of dice 130 and 132, similar with that of the IC die stack 104 shown in FIG. 2a. Comparing to the dice 124a and 124b in FIG. 2a, each of the devices 152a and 152b at the second tier 132 of the IC die stack 160 functions as an IC die stack. For example, the device 152a includes four (4) dice 1521a, 1522a, 1523a, and 1524a stacked on top of each other, in which the die 1524a is connected with the bridge die 106. The device 152b includes two (2) dice 1521b and 1522b stacked on top of each other, in which the die 1521b is connected with the bridge die 106. In another example, one of the devices 152a and 152b may be a single die, while the other of the devices 152a and 152b may be an IC die stack. When the devices 152a and 152b may not have a similar height, the gap fill material 116 is used to fill the volume generated due to the height difference.

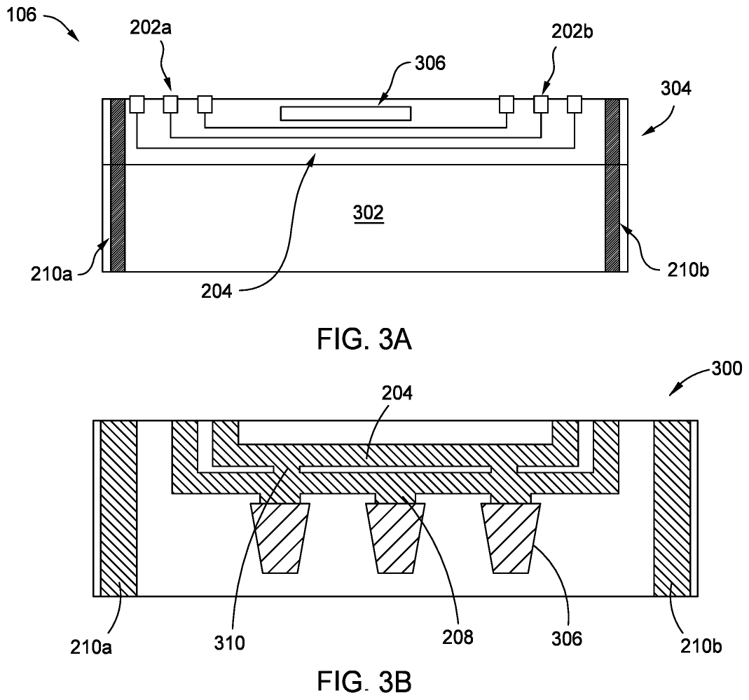

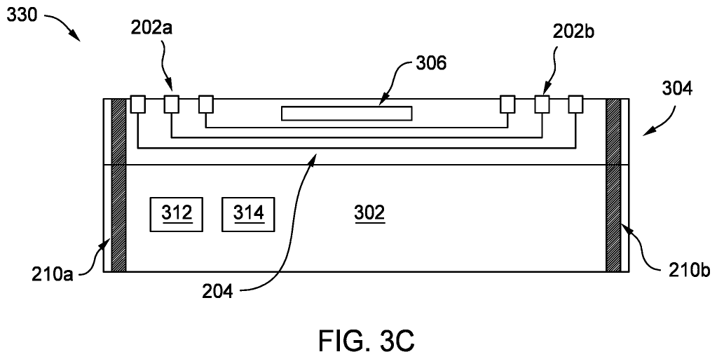

FIG. 3a illustrates a schematic cross-sectional view of a bridge die 106, according to an embodiment. The bridge die 106 includes a substrate 302 and a buildup layer 304. The substrate 302 may be a silicon substrate, a glass substrate, or other suitable substrate. The buildup layer 304 may also be known as a redistribution layer (RDL). The buildup layer 304 includes two or more metal layers that are patterned for form metal routings that defined the routing connections 204. Dielectric layers are disposed between the metal layers to prevent shorting between the routing connections 204. The routing connections 204 terminate at the hybrid bond pads used to form one side of the hybrid bonds 202a and 202b electrically and mechanically coupling the routing connections 204 of the bridge die 106 to the other dice 124, 114.

According to an embodiment, one or more passive devices 306, such as a capacitor, resistor, inductor, and the like, may also be integrated in the buildup layer 304 to improve power or signal integrity. The passive devices 306 are coupled by the routing connections 204 to one or both of the dice 124, 114 connected to the bridge die 106. The passive devices 306 are capable of improving the signal quality transmitted by the routing connections. The passive devices 306 may be disposed adjacent to the signal routing connections.

FIG. 3b illustrates a schematic cross-sectional view of a bridge die 300, according to an embodiment. The bridge die 300 includes a plurality of integrated passive devices 306 disposed beneath the routing connections 204. A first connection 308 couples the routing connections 204 with the integrated passive devices 306. The routing connections 204 may also be coupled by a second connection 310 at locations adjacent to the integrated passive devices 306. In this way, one integrated passive devices 306 may be shared by a plurality of routing connections 204.

FIG. 3c illustrates a schematic cross-sectional view of a bridge die 330 having one or more integrated active devices, according to an embodiment. The bridge die 330 includes one or more active devices 312 and 314. The active devices may function as a memory controller circuitry, including an on-package memory controller 312 and an off-package memory controller 314. The on-package memory controller circuit 312 is configured to control memories disposed within the package 110. The off-package memory controller circuitry 314 is generally configured to control communications with memory that is not within (e.g., remote from) the chip package 110. In one example, the off-package memory controller circuitry 314 is configured to communicate through the package substrate with the one or more memory devices that are mounted to the PCB; or stated differently, memory devices that are located within the electronic device 100 but are not within the chip package 110. The active devices 312 and 314 may be formed within the substrate 302 of the bridge die 330. In addition to the active devices 312 and 314, the bridge die 330 may also include one or more passive device 306.

In one example, the memory controller circuitry 312 and 314 include one or more of active circuitries, such as interconnect circuitry, high bandwidth memory attached last level cache (HALL) circuitry, tag circuitry, memory circuitry, memory controller circuitry, memory devices, and direct memory access (DMA) circuitry. The silicon bridge 330 may include coherency station circuitry that includes N coherency station circuitries. The HALL circuitry includes N HALL circuitries, the tag circuitry includes N tag circuitries, and the memory controller circuitry includes N memory controller circuitries. N is greater than 1. In one example, N is 2, 4, or 8, or more.

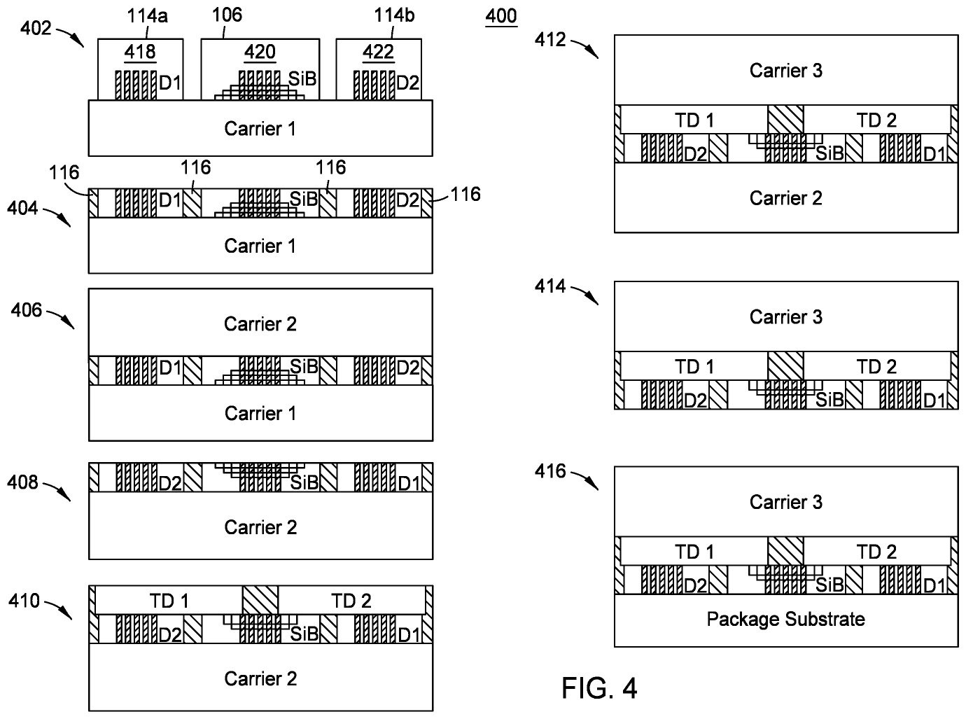

FIG. 4 is a schematic manufacturing process 400 for making an IC die stack according to an embodiment of the present application. Before operation 402, the dice 114a, 114b and the bridge die 106 have been fabricated with known techniques. As the dice 114a, 114b and the bridge die 106 may be made of different techniques, the dice 114, 114b and the bridge die 106 may have different heights. According to an embodiment, each of the dice 114a, 114b and the bridge die 106 include certain depths of spare materials 418, 420, and 422, respectively. The spare materials 418, 420, and 422 have no electrical traces or devices and are designed to be subsequently removed, such as grinding, milling, or other processes. The spare materials 418, 420, and 422 are disposed at an inactive side of the dice 114a, 114b and the bridge die 106.

At operation 402, the dice 114a, 114b and the bridge die 106 are mounted to a No. 1 carrier with active sides contacting the No. 1 carrier. The No. 1 carrier may be made of any material that can support dice in a chip making process, such as a silicon substrate or any other suitable substrates.

At operation 404, the gap fill material 116 is deposited in the gaps among the dice 114a, 114b and the bridge die 106. Then, the spare materials 418, 420, and 422 and the gap fill material 116 are removed by grinding, milling, or any other suitable techniques. As a result, the dice 114a, 114b and the bridge die 106 have a similar height and the TSVs are exposed.

At operation 406, a No. 2 carrier is mounted on the dice 114a, 114b and the bridge die 106 at a side opposite to the No. 2 carrier. The No. 2 carrier may be made of a material similar to that of the No. 1 carrier.

At operation 408, the No. 1 carrier is removed, thus exposing active sides of the dice and the bridge die. Then, the No. 2 carrier is flipped, causing the active side to face upward.

At operation 410, the dice of a higher tier, such as TD1 and TD2, are mounted on top of the dice 114a, 114b and the bridge die 106, which are disposed at the 1^{st} tier. Additional tiers of dice may be mounted on top of dice TD1 and TD2. After the dices are mounted, the gap fill material is deposited in the gaps among the top tier dice.

At operation 412, a No. 3 carrier is mounted on top of the dice TD1 and TD2. The No. 3 carrier may be made of a material similar as the No. 1 or No. 2 carriers. The No. 3 carrier may be thinned in a later process to meet package requirements. In the chip package 100, the filler die 126 corresponds to the No. 3 carrier.

At operation 414, the No. 2 carrier is removed to expose the communication interface of the dice 114a, 114b and the bridge die 106.

At operation 416, the No. 3 and the dice are mounted on a package substrate, an interposer, or another substrate, which couples the communication interface with another electrical component.

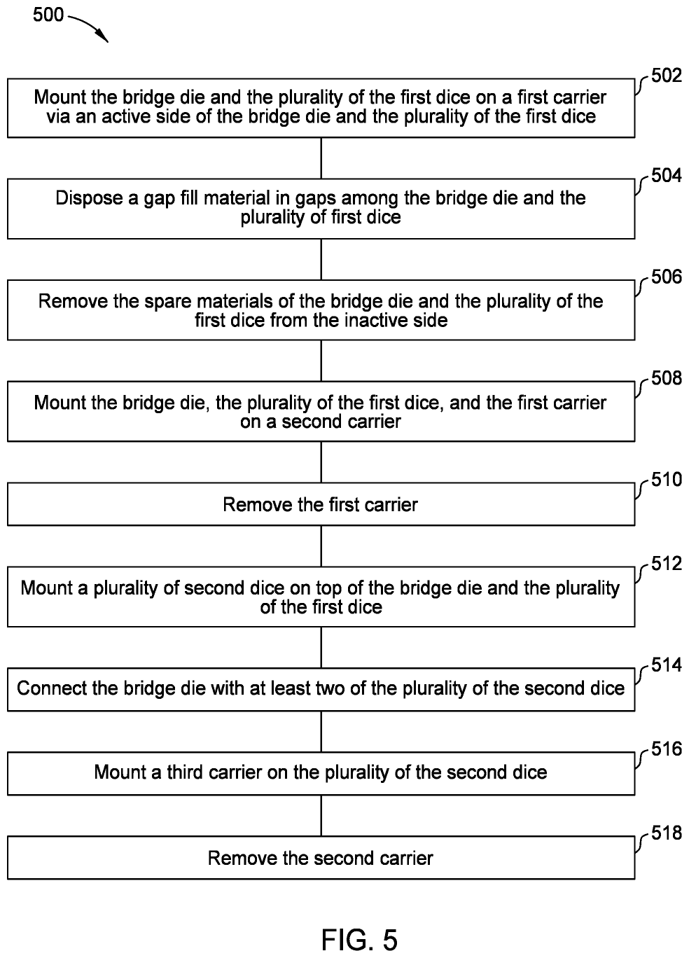

FIG. 5 illustrates a method 500 of manufacturing an integrated circuit die stack. The method includes manufacturing a bridge die and a plurality of first dice, the bridge die and the plurality of first dice including spare materials at an inactive side. At operation 502, the bridge die and the plurality of the first dice is mounted on a first carrier via an active side of the bridge die and the plurality of the first dice. At operation 504, a gap fill material is disposed in gaps among the bridge die and the plurality of first dice. At operation 506, the spare materials of the bridge die and the plurality of the first dice are removed from the inactive side. At operation 508, the bridge die, the plurality of the first dice, and the first carrier are mounted on a second carrier. At operation 510, the first carrier is removed. At operation 512, a plurality of second dice are mounted on top of the bridge die and the plurality of the first dice. At operation 514, the bridge die is connected with at least two of the plurality of the second dice. At operation 516, a third carrier is mounted on the plurality of the second dice. At operation 518, the second carrier is removed, and the IC die stack is ready to be mounted to a package substrate, an interposer, or another substrate. The method 500 is not limited to making an IC die stack with only two tiers. According to an embodiment, the operations 512 and 514 may be repeated to include additional tiers of dices to an IC die stack.

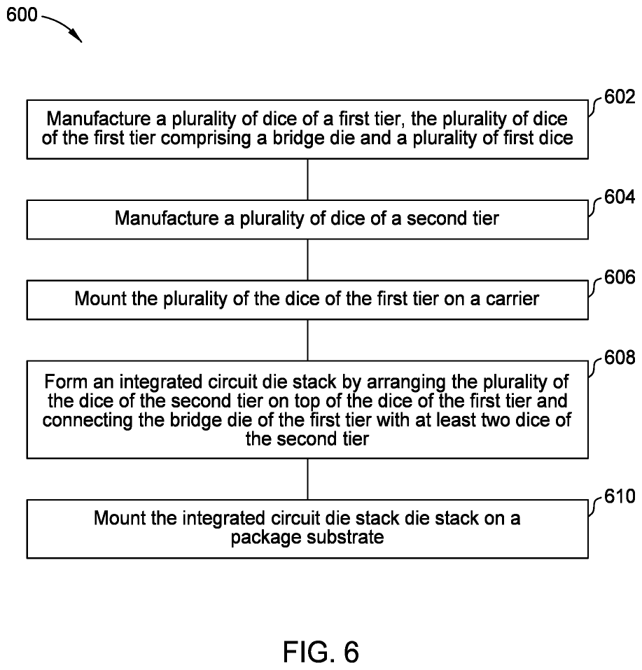

FIG. 6 illustrates another method of manufacturing an integrated circuit die stack according to an embodiment of the present application. At operation 602, a plurality of dice of a first tier are manufactured. The plurality of dice of the first tier include a bridge die and a plurality of first dice. At operation 604, a plurality of dice of a second tier are manufactured. At operation 606, the plurality of the dice of the first tier are arranged on a carrier. At operation 608, the plurality of the dice of the second tier are arranged on top of the dice of the first tier to form an integrated circuit die stack. During the arrangement of the dice of the second tier, the bridge die of the first tier connects with at least two dice of the second tier. The dice of the second tier may be collectively arranged on the first tier by using a common carrier or may be individually arranged. At operation 610, the integrated circuit die stack die stack is mounted on a package substrate.

While the foregoing is directed to embodiments of the present invention, other and further embodiments of the invention may be devised without departing from the basic scope thereof, and the scope thereof is determined by the claims that follow.

What is claimed is:

1. An integrated circuit die stack comprising:
a plurality of first integrated circuit dice disposed in a first tier of the integrated circuit die stack, the plurality of the first integrated circuit dice comprising a first integrated circuit die and a bridge die; and
a plurality of second integrated circuit dice disposed in a second tier of the integrated circuit die stack, the plurality of the second integrated circuit dice stacked vertically above the plurality of the first integrated circuit dice of the first tier, the plurality of the second integrated circuit dice comprising a second integrated circuit die and a third integrated circuit die,
wherein the bridge die couples with both the second integrated circuit die and the third integrated circuit die.

2. The integrated circuit die stack of claim 1, wherein the bridge die comprises routing connections between the second and third integrated circuit dice.

3. The integrated circuit die stack of claim 2, wherein the routing connections are coupled by a plurality of hybrid bonds of the second and third integrated circuit dice.

4. The integrated circuit die stack of claim 3, wherein a pitch of the hybrid bonds is less than 10 μm.

5. The integrated circuit die stack of claim 4, wherein the routing connections are defined by a redistribution layer (RDL) formed on a substrate.

6. The integrated circuit die stack of claim 2, wherein the bridge die comprises passive integrated devices.

7. The integrated circuit die stack of claim 4, wherein the bridge die comprises a plurality of through silicon vias.

8. The integrated circuit die stack of claim 1, further comprising a plurality of hybrid bonds coupling the first integrated circuit die with the second integrated circuit die and/or the third integrated circuit die.

9. The integrated circuit die stack of claim 1, wherein the second integrated circuit die covers an entirety of the first integrated circuit die.

10. The integrated circuit die stack of claim 1, further comprising a filler die disposed in a third tier of the integrated circuit die stack, the filler die not electrically connected to the second plurality of integrated circuit dies in the second tier.

11. The integrated circuit die stack of claim 10, further comprising:
a stiffener surrounding the integrated circuit die stack, and
a cover coupled to the stiffener and the filler die.

12. An integrated circuit die package assembly comprising:
a package substrate; and
an integrated circuit die stack disposed above the package substrate within the integrated circuit die package assembly, the integrated circuit die stack comprising:
a first integrated circuit die and a bridge die disposed in a first tier of the die stack; and
a second integrated circuit die and a third integrated circuit die disposed in a second tier that is stacked vertically above the first tier,
wherein the bridge die couples with both the second integrated circuit die and the third integrated circuit die.

13. The integrated circuit die package assembly of claim 12, wherein the bridge die comprises routing connections between the second and third integrated circuit dice.

14. The integrated circuit die package assembly of claim 13, wherein the routing connections are coupled by a plurality of hybrid bonds of the second and third integrated circuit dice.

15. The integrated circuit die package assembly of claim 14, wherein a pitch of the hybrid bonds is less than 10 μm.

16. The integrated circuit die package assembly of claim 15, the routing connections are defined by a redistribution layer (RDL) formed on a substrate.

17. The integrated circuit die package assembly of claim 13, wherein the bridge die comprises passive integrated devices.

18. The integrated circuit die package assembly of claim 14, wherein the bridge die comprises a plurality of through silicon vias.

19. The integrated circuit die package assembly of claim 12, wherein the plurality of the integrated circuit dice of the first tier are mounted on an interposer or a package substrate.

20. A method for manufacturing an integrated circuit die stack, the method comprising:
mounting the plurality of the dice of a first tier on a carrier, the plurality of dice of the first tier comprising a bridge die;
arranging a plurality of the dice of the second tier on top of the dice of the first tier;
forming an integrated circuit die stack by connecting the dice of the first tier with the dice of the second tier, wherein the connecting comprises connecting the bridge die with at least two dice of the second tier; and
mounting the integrated circuit die stack die stack on a package substrate.
